(19) United States
(12) Patent Application Publication
(10) Pub. No.: US 2024/0324210 A1
(43) Pub. Date: Sep. 26, 2024

(54) SEMICONDUCTOR MEMORY AND METHOD OF MANUFACTURING SEMICONDUCTOR MEMORY

(71) Applicant: Kioxia Corporation, Tokyo (JP)

(72) Inventors: Takuya SUZUKI, Kuwana Mie (JP); Soh KOIKE, Tachikawa Tokyo (JP)

(73) Assignee: Kioxia Corporation, Tokyo (JP)

(21) Appl. No.: 18/592,055

(22) Filed: Feb. 29, 2024

(30) Foreign Application Priority Data
Mar. 20, 2023 (JP) 2023-044018
Nov. 27, 2023 (JP) 2023-200016

(51) Int. Cl. H10B 43/27

(52) U.S. Cl. CPC H10B 43/27

(57) ABSTRACT

A semiconductor memory includes a first stacked body, a first separation portion, a second stacked body, a third stacked body, and a bit line. The first stacked body is configured such that a plurality of first insulating films and a plurality of first conductive films are alternately stacked in a first direction. The first separation portion is adjacent to the first stacked body in a second direction intersecting the first direction. The second stacked body is adjacent to the first separation portion in the second direction. The second stacked body is configured such that a plurality of second insulating films and a plurality of second conductive films are alternately stacked in the first direction. The third stacked body is adjacent to the second stacked body in the second direction. The third stacked body is configured such that the plurality of second insulating films and a plurality of third insulating films are alternately stacked in the first direction. At least one layer of a third conductive film among the plurality of second conductive films has a first portion and a second portion. The second portion is located below the first portion in the first direction and is configured to protrude more into the third stacked body than the first portion in the second direction.

### CROSS-REFERENCE TO RELATED APPLICATION

This application is based upon and claims the benefit of priority from Japanese Patent Application No. 2023-044018, filed Mar. 20, 2023, and Japanese Patent Application No. 2023-200016, filed Nov. 27, 2023, the entire contents of which are incorporated herein by reference.

### FIELD

Embodiments described herein relate generally to a semiconductor memory and a method of manufacturing a semiconductor memory.

### BACKGROUND

A semiconductor memory including a substrate, a plurality of wiring layers stacked in a first direction intersecting the surface of the substrate, and a memory structure extending in the first direction through the plurality of wiring layers.

### DESCRIPTION OF THE DRAWINGS

FIG. 1 is a block diagram showing a semiconductor memory and a memory controller according to at least one embodiment.

FIG. 2 is a diagram showing an equivalent circuit of a portion of a memory cell array of the semiconductor memory according to at least one embodiment.

FIG. 3 is a plan view showing a portion of the semiconductor memory according to at least one embodiment.

FIG. 4 is a cross-sectional view showing a portion of the semiconductor memory according to at least one embodiment.

FIG. 5 is an enlarged cross-sectional view of a first columnar portion and a second columnar portion in the vicinity of a boundary between a cell array area and an end area of the semiconductor memory according to at least one embodiment.

FIG. 6 is a cross-sectional view showing the vicinity of the first columnar portion of the semiconductor memory according to at least one embodiment.

FIG. 7 is an enlarged view of a region X shown in FIG. 5.

FIG. 8 is an enlarged cross-sectional view of the vicinity of a conductive film of the semiconductor memory according to at least one embodiment.

FIG. 9 is an enlarged view of a region Y shown in FIG. 5.

FIG. 10 is a cross-sectional view illustrating a method of manufacturing the semiconductor memory according to at least one embodiment.

FIG. 11 is a cross-sectional view illustrating a method of manufacturing the semiconductor memory according to at least one embodiment.

FIG. 12 is a cross-sectional view illustrating a method of manufacturing the semiconductor memory according to at least one embodiment.

FIG. 13 is a cross-sectional view illustrating a method of manufacturing the semiconductor memory according to at least one embodiment.

FIG. 14 is a cross-sectional view illustrating a method of manufacturing the semiconductor memory according to at least one embodiment.

FIG. 15 is a cross-sectional view illustrating a method of manufacturing the semiconductor memory according to at least one embodiment.

FIG. 16 is a cross-sectional view illustrating a method of manufacturing the semiconductor memory according to at least one embodiment.

### DETAILED DESCRIPTION

Embodiments provide a semiconductor memory that is capable of achieving an improvement in electrical characteristics.

In general, according to at least one embodiment, a semiconductor memory includes a first stacked body, a first separation portion, a second stacked body, a third stacked body, a bit line. The first stacked body is configured such that a plurality of first insulating films and a plurality of first conductive films are alternately stacked in a first direction. The first separation portion is adjacent to the first stacked body in a second direction intersecting the first direction. The first separation portion extends in the first direction and a third direction intersecting the first and second directions. The second stacked body is adjacent to the first separation portion in the second direction. The second stacked body is configured such that a plurality of second insulating films and a plurality of second conductive films are alternately stacked in the first direction. The third stacked body is adjacent to the second stacked body in the second direction. The third stacked body is configured such that a plurality of second insulating films and a plurality of third insulating films are alternately stacked in the first direction. The bit line is provided on an upper side of the first stacked body, in which the upper side is one side in the first direction. The first stacked body includes a first semiconductor layer. The first stacked body includes a first columnar portion extending in the first direction. At least one layer of a third conductive film among the plurality of second conductive films has a first portion and a second portion. The second portion is located below the first portion in the first direction and is configured to protrude more into the third stacked body than the first portion in the second direction.

Hereinafter, a semiconductor memory and a method of manufacturing a semiconductor memory according to an embodiment will be described with reference to the accompanying drawings. In the following description, components having the same or similar functions are denoted by the same reference numerals. In addition, repeated descriptions of these components may be omitted. The drawings are schematic or conceptual, and relationships between the thickness and width of portions, the proportionality of sizes between portions, and the like are not necessarily the same as the actual values thereof. In the present specification, “connection” is not limited to a case of physical connection and also includes a case of electrical connection. In the present application, “parallel,” “orthogonal,” and “identical” also includes cases of “substantially parallel,” “substantially orthogonal,” and “substantially identical,” respectively. In the present application, “extending in an A direction” means, for example, that a dimension in the A direction is larger than the smallest dimension among dimensions in an X direction, a Y direction, and a Z direction, which will be described later. The “A direction” mentioned here is an any direction.

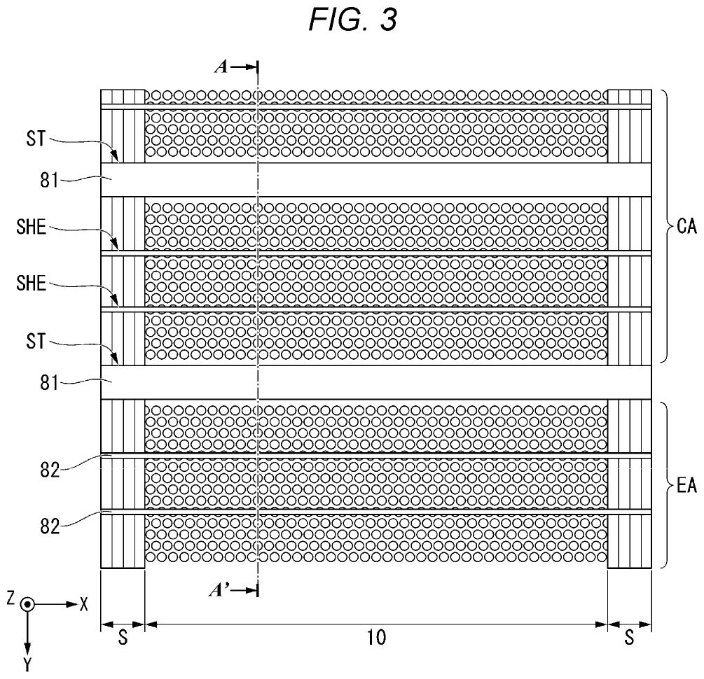

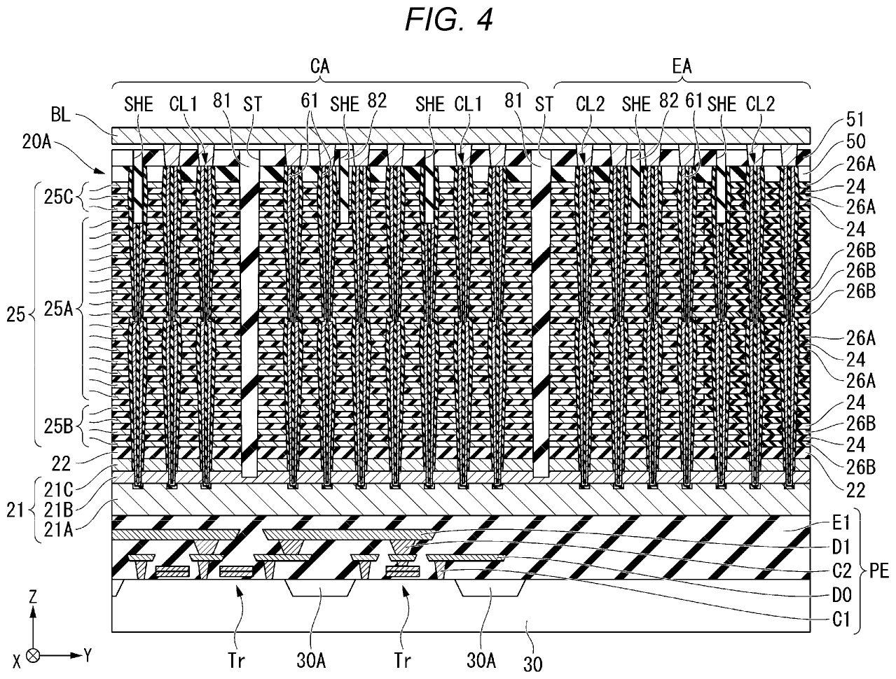

First, a +X direction, a −X direction, a +Y direction, a −Y direction, a +Z direction, and a −Z direction will be defined. The +X direction, the −X direction, the +Y direction, and the −Y direction are directions along the surface of a substrate 30 (see FIG. 4), which will be described later. The +X direction is one of the directions in which a separation portion 81 (see FIG. 3), which will be described later, extends. The −X direction is a direction opposite to the +X direction. When the +X direction and the −X direction are not distinguished from each other, they are simply referred to as the “X direction”. The +Y direction and the −Y direction are directions that intersect (for example, are orthogonal to) the X direction. The +Y direction is one of the directions in which a bit line BL (see FIG. 4), which will be described later, extends. The −Y direction is a direction opposite to the +Y direction. When the +Y direction and the −Y direction are not distinguished from each other, they are simply referred to as the “Y direction”. The +Z direction and the −Z direction are directions that intersect (for example, are orthogonal to) the X direction and the Y direction, and are thickness directions of the substrate 30 (see FIG. 4). The +Z direction is a direction from the substrate 30 to the bit line BL, which will be described later. The −Z direction is a direction opposite to the +Z direction. When the +Z direction and the −Z direction are not distinguished from each other, they are simply referred to as the “Z direction”. The Z direction corresponds to a direction perpendicular to the surface of the substrate 30 used to form a semiconductor memory 1. In the present specification, the “+Z direction” may be referred to as “upward” and the “−Z direction” may be referred to as “downward”. However, these expressions are for convenience of description and do not define the direction of gravity. The +Z direction is an example of a “first direction”. The +Y direction is an example of a “second direction”. The +X direction is an example of a “third direction”.

Among the drawings to be referred to below, in each of a plan view and a cross-sectional view, illustration of some components such as wirings, contacts, and interlayer insulating films are omitted as appropriate to facilitating the viewing of the drawings.

### Embodiment

### <1. Configuration of Semiconductor Memory>

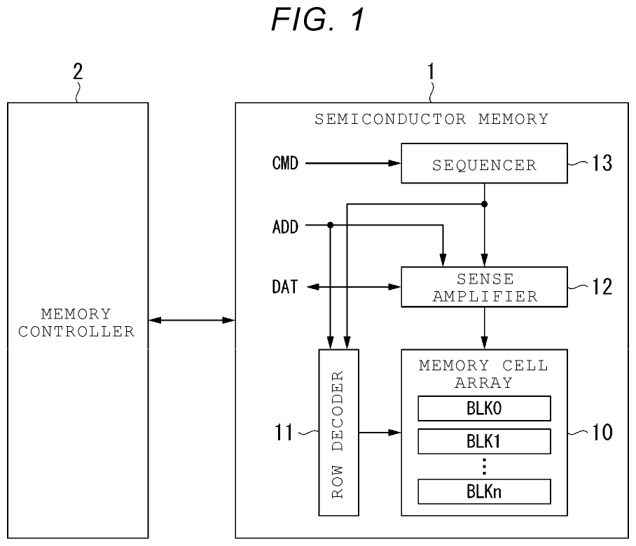

FIG. 1 is a block diagram showing the semiconductor memory 1 and a memory controller 2. The semiconductor memory 1 is a nonvolatile semiconductor memory, and is, for example, a NAND flash memory. The semiconductor memory 1 is controlled by the memory controller 2. Communication between the semiconductor memory 1 and the memory controller 2 is based on, for example, the NAND interface standard. The semiconductor memory 1 includes, for example, a memory cell array 10, a row decoder 11, a sense amplifier 12, and a sequencer 13.

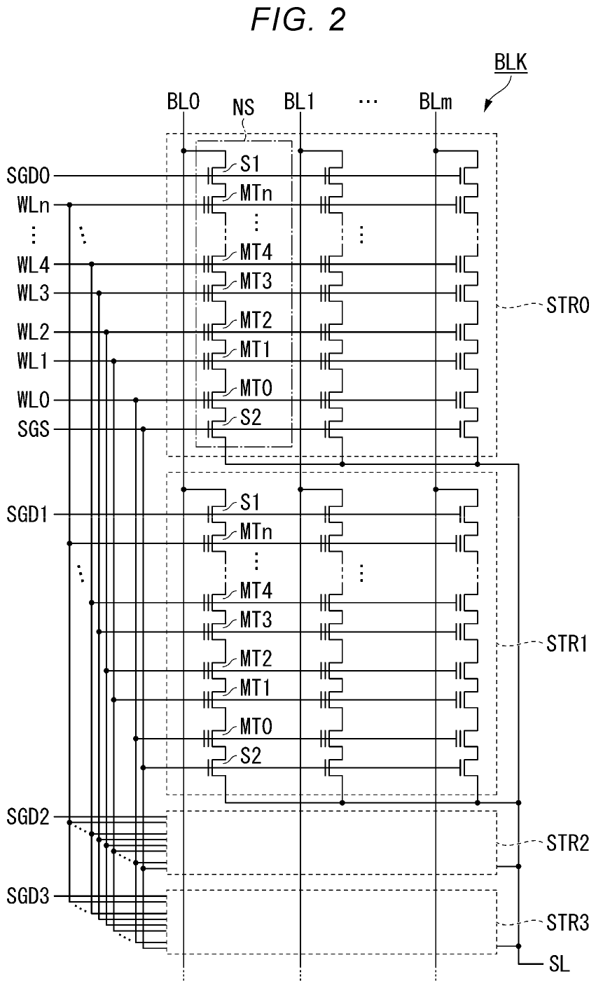

The memory cell array 10 includes a plurality of blocks BLK0 to BLKn (n is an integer of 1 or more). Each block BLK is a set of nonvolatile memory cell transistors MT (see FIG. 2). The memory cell array 10 is provided with a plurality of bit lines and a plurality of word line. Each of the memory cell transistors MT is associated with one bit line and one word line.

The row decoder 11 selects one block BLK based on address information ADD received from the external memory controller 2. The row decoder 11 controls a data writing operation and a data reading operation for the memory cell array 10 by applying a desired voltage to each of the plurality of word lines.

The sense amplifier 12 applies a desired voltage to each bit line in accordance with write data DAT received from the memory controller 2. The sense amplifier 12 determines data stored in the memory cell transistor MT based on the voltage of the bit line, and transmits the determined read data DAT to the memory controller 2.

The sequencer 13 controls the operation of the entire semiconductor memory 1 based on a command CMD received from the memory controller 2.

The semiconductor memory 1 and the memory controller 2 may be combined to constitute one memory system. Examples of the memory system include a memory card, a solid state drive (SSD), and the like.

Next, a configuration of the memory cell array 10 will be described. FIG. 2 is a diagram showing an equivalent circuit of a portion of the memory cell array 10. FIG. 2 shows an extracted block BLK provided in the memory cell array 10. The block BLK includes a plurality of (for example, four) strings STR0 to STR3.

Each of the strings STR0 to STR3 is a set of a plurality of NAND strings NS. One end of each NAND string NS is connected to one of the bit lines BL0 to BLm (m is an integer of 1 or more). The other end of the NAND string NS is connected to a source line SL. Each NAND string NS includes a plurality of memory cell transistors MT0 to MTn (n is an integer of 1 or more), a first select transistor S1, and a second select transistor S2.

The plurality of memory cell transistors MT0 to MTn are electrically connected to each other in series. The memory cell transistor MT includes a control gate and a memory stacked film, and stores data in a non-volatile manner. The memory cell transistor MT changes the state of the memory stacked film in accordance with a voltage applied to the control gate. For example, charge is stored in a charge storage film provided in the memory stacked film. The control gate of the memory cell transistor MT is connected to one of the corresponding word lines WL0 to WLn. The memory cell transistor MT is electrically connected to the row decoder 11 via the word line WL.

The first select transistor S1 in each NAND string NS is connected between the plurality of memory cell transistors MT0 to MTn and one of the bit lines BL0 to BLm. A drain of the first select transistor S1 is connected to one of the bit lines BL0 to BLm. A source of the first select transistor S1 is connected to the memory cell transistor MTn. The control gate of the first select transistor S1 in each NAND string NS is connected to one of the select gate lines SGD0 to SGD3. The first select transistor S1 is electrically connected to the row decoder 11 via the select gate line SGD. The first select transistor S1 connects the NAND string NS and the bit line BL when a predetermined voltage is applied to the select gate line SGD corresponding to the first select transistor S1 among the select gate lines SGD0 to SGD3.

The second select transistor S2 in each NAND string NS is connected between the plurality of memory cell transistors MT0 to MTn and the source line SL. A drain of the second select transistor S2 is connected to the memory cell transistor MT0. A source of the second select transistor $2 is connected to the source line SL. A control gate of the second select transistor S2 is connected to the select gate line SGS. The second select transistor S2 is electrically connected to the row decoder 11 via the select gate line SGS. The second select transistor S2 connects the NAND string NS and the source line SL when a predetermined voltage is applied to the select gate line SGS.

The memory cell array 10 may have a circuit configuration other than that described above. For example, the number of strings STR provided in each block BLK, the number of memory cell transistors MT provided in each NAND string NS, and the number of select transistors STD and STS may be changed. The NAND string NS may include one or more dummy transistors.

FIG. 3 is a plan view showing a portion of the semiconductor memory 1 according to the present embodiment.

As shown in FIG. 3, the semiconductor memory 1 according to the present embodiment includes the memory cell array 10 and, for example, staircase portions S provided at both ends of the memory cell array 10 in the X direction. Each slit ST is provided from one staircase unit S to the other staircase unit S through the memory cell array 10. The memory cell array 10 has a cell array area. The NAND strings NS are integrated in the cell array area.

### <1.1 Memory Cell Array>

Next, an example of the structure of the memory cell array 10 of the semiconductor memory 1 will be described. FIG. 4 is a cross-sectional view taken along an A-A′ plane in FIG. 3.

As shown in FIG. 4, the memory cell array 10 of the semiconductor memory 1 includes the substrate 30, a circuit layer PE, a cell array area CA, and an end area EA.

The substrate 30 is, for example, a silicon substrate. A plurality of element separation regions 30A are located in a surface region of the substrate 30. The element separation region 30A contains, for example, silicon oxide. A source region and a drain region of a transistor Tr are located between the element separation regions 30A adjacent to each other in the Y direction.

The circuit layer PE is located on the substrate 30. The circuit layer PE includes the row decoder 11, the sense amplifier 12, and the sequencer 13 of the semiconductor memory 1. The circuit layer PE includes, for example, the plurality of transistors Tr, a plurality of wiring layers D0 and D1, and a plurality of vias C1 and C2. The plurality of transistors Tr, the plurality of wiring layers D0 and D1, and the plurality of vias C1 and C2 are located in an insulating layer E1. The insulating layer E1 contains, for example, silicon oxide. The via C1 connects a source region or a drain region of the transistor Tr and the wiring layer DO. The via C2 connects a gate region of transistor Tr and the wiring layer D1. The vias C1 and C2 and the wiring layers D0 and D1 contain, for example, tungsten.

### (Cell Array Area CA)

The cell array area CA includes a first stacked body 20A in which a plurality of insulating films 24 and a plurality of conductive films 25 are alternately stacked in the Z direction, and a plurality of first columnar portions CL1 including a semiconductor body 61. In the present embodiment, the insulating film 24 is an example of a “first insulating film”, and the conductive film 25 is an example of a “first conductive film” and a “second conductive film” to be described later. The semiconductor body 61 is an example of a “first semiconductor layer” and a “second semiconductor layer.”

The first stacked body 20A includes a conductive film 21, an insulating film 22, a plurality of conductive films 25, and a plurality of insulating films 24 in order from the substrate 30 side in the Z direction. The conductive film 21 and the plurality of conductive films 25 extend in the X direction and the Y direction, respectively. The insulating film 22 and the plurality of insulating films 24 extend in the X direction and the Y direction, respectively. The plurality of insulating films 24 and the plurality of conductive films 25 are alternately stacked one by one in the Z direction.

The insulating film 22 is located between the conductive film 21 and the conductive film 25. The insulating film 24 is located between the conductive films 25 adjacent to each other in the Z direction. The insulating film 24 insulates between two conductive films 25 adjacent to each other in the Z direction. The number of layers of the insulating film 24 is determined by the number of layers of the conductive film 25. The film thickness of the insulating film 24 is, for example, 20 nm or less. The insulating film 22 and the plurality of insulating films 24 contain, for example, silicon oxide.

The plurality of conductive films 25 extend in the X direction and the Y direction, respectively. That is, the conductive films 25 are formed into plate shapes that extend along the X direction and the Y direction. The conductive film 25 is, for example, tungsten or polysilicon doped with impurities. The number of layers of the conductive film 25 is freely set.

The plurality of conductive films 25 include a plurality of conductive films 25A stacked in the Z direction, a conductive film 25B located between the substrate 30 and the plurality of conductive films 25A in the Z direction, and a conductive film 25C located on a side opposite to the substrate 30 with respect to the plurality of conductive films 25A in the Z direction.

Among the plurality of conductive films 25, the conductive film 25B, which is at least one layer from the bottom of the first stacked body 20A, may function as a select gate line of the source-side (source-side select gate line) SGS. The conductive film 25B functioning as the source-side select gate line SGS may be a single layer or a plurality of layers. That is, the source-side select gate line SGS may be configured with one conductive film 25 or a plurality of conductive films 25. Further, when the source-side select gate line SGS is configured with a plurality of layers, the plurality of conductive films 25B may be respectively configured with different conductors.

Among the conductive films 25, the conductive film 25C, which is at least one layer from above the first stacked body 20A, functions as a select gate line of the drain-side (drain-side select gate line) SGD. The conductive film 25C functioning as the drain-side select gate line SGD may be a single layer or a plurality of layers. That is, the drain-side select gate line SGD may be configured with one conductive film 25C, or may be configured with a plurality of conductive films 25C. When the drain-side select configured with a plurality of layers, the conductive films 25C may be respectively configured with different conductors.

Among the plurality of conductive films 25, a plurality of conductive films 25 (that is, the conductive films 25A) other than the source-side select gate line SGS and the drain-side select gate line SGD function as the word lines WL. For example, the plurality of conductive films 25A functioning as the word lines WL surround the outer periphery of the first columnar portions CL1.

The conductive film 21 is disposed above the circuit layer PE. The conductive film 21 includes semiconductor layers 21A, 21B, and 21C. The semiconductor layer 21A is on the circuit layer PE. The semiconductor layer 21A is, for example, an n-type semiconductor. The semiconductor layer 21A is, for example, polysilicon doped with impurities. The semiconductor layer 21B is located on the semiconductor layer 21A. The semiconductor layer 21B is in contact with the semiconductor body 61 of the first columnar portion CL1. The semiconductor layer 21B is, for example, an epitaxial film doped with impurities. The semiconductor layer 21B contains, for example, phosphorus. The semiconductor layer 21C is located on the semiconductor layer 21B. The semiconductor layer 21C is, for example, an n-type or undoped semiconductor.

Cover insulating layers 50 and 51 are located above the uppermost conductive film 25C of the first stacked body 20A. The cover insulating layers 50 and 51 insulate the first stacked body 20A and the bit line BL from each other. The cover insulating layers 50 and 51 contain, for example, silicon oxide.

The bit line BL is formed above the cover insulating layer 51 in a line shape extending, for example, in the Y direction, and is electrically connected to the first columnar portion CL1. The plurality of bit lines BL are located in the X direction in a region which is not shown in the drawing.

The plurality of first columnar portions CL1 are provided in the first stacked body 20A. Each of the plurality of first columnar portions CL1 extends in the Z direction. For example, the plurality of first columnar portions CL1 penetrate the plurality of conductive films 25 and the semiconductor layers 21B and 21C, respectively, in the Z direction. The first columnar portion CL1 includes a lower columnar portion LCL1 and an upper columnar portion UCL1 provided in contact with an upper portion of the lower columnar portion LCL1. The lower columnar portion LCL1 is in contact with the semiconductor layer 21A. The upper columnar portion UCL1 is in contact with the cover insulating layer 50.

Next, the structures of the first columnar portion CL1 and its vicinity will be described in detail.

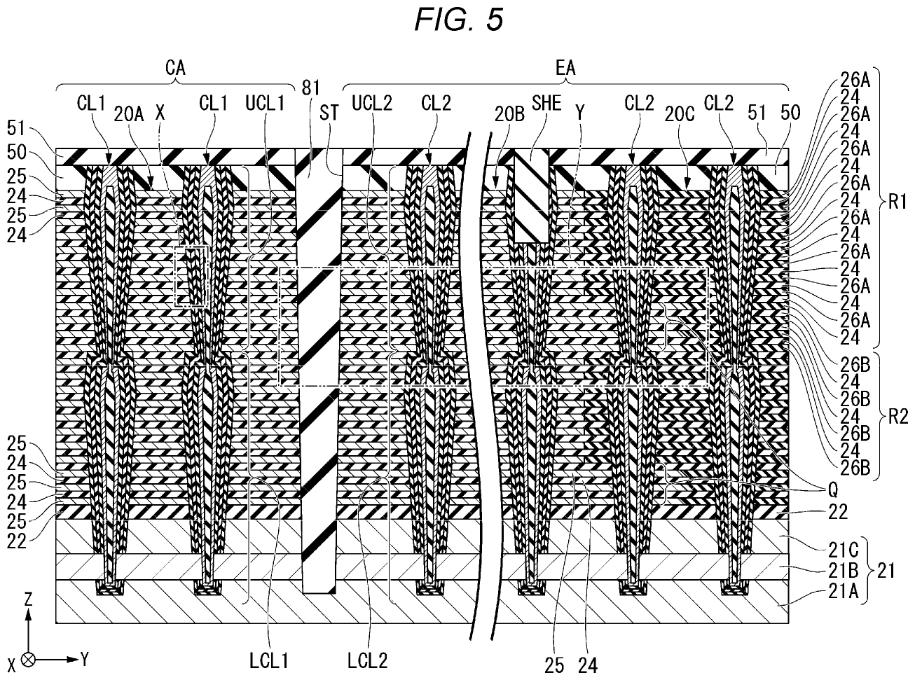

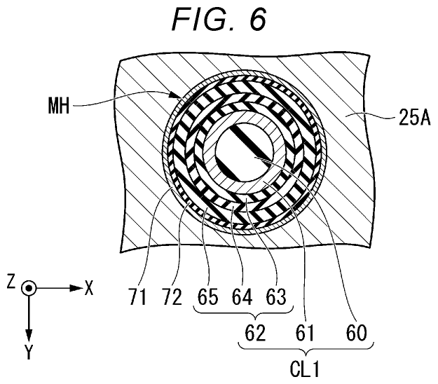

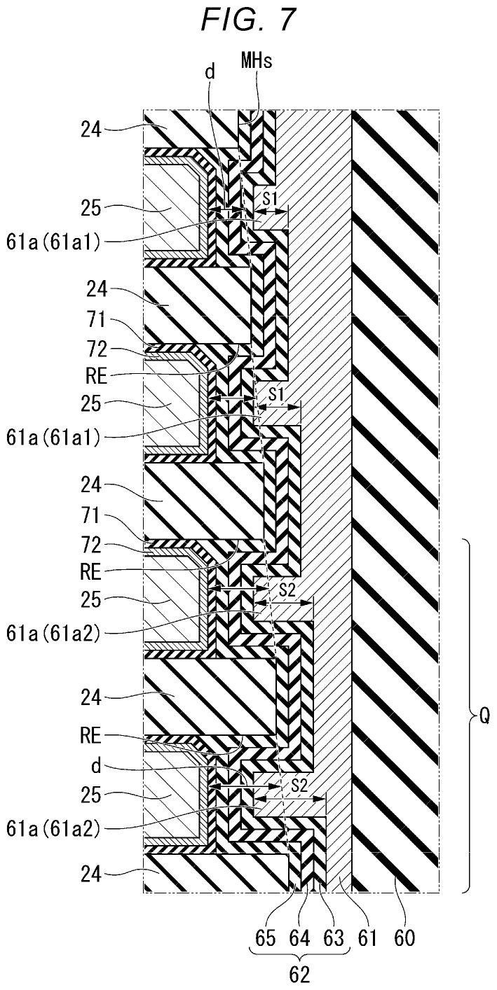

FIG. 5 is an enlarged cross-sectional view of the first columnar portion CL1 and the second columnar portion CL2 in the vicinity of a boundary between a cell array area CA and an end area EA. FIG. 6 is a cross-sectional view of the vicinity of the first columnar portion CL1 taken along the conductive film 25A. FIG. 6 shows a cross-section of the first columnar portion CL1 taken along an XY plane. FIG. 7 is an enlarged view of a region X shown in FIG. 5.

Each of the plurality of first columnar portions CL1 is formed in a memory hole MH, and includes an insulating core 60, a semiconductor body 61, and a memory stacked film 62 in order from the inside. In the present embodiment, the semiconductor body 61 is an example of a “first semiconductor layer”.

As shown in FIG. 7, a plurality of recesses RE recessed toward the conductive film 25 side are formed in a side wall MHs of the memory hole MH. The plurality of recesses RE are grooves formed in a side wall MHs at a position corresponding to the conductive film 25, among the side walls MHs of memory holes MH formed in a cylindrical shape, by etching so as to be recessed toward the conductive film 25 side. In other words, the recesses RE are located further from the memory hole MH than an end surface of the conductive film 25 on the memory hole MH side and an end surface of the insulating film 24 on the memory hole MH side.

Depths d of the respective recesses RE are different in the Z direction. As will be described later, the first columnar portion CL1 has a shape in which a diameter on a side close to the substrate 30 becomes smaller. In other words, the memory hole MH also has a shape in which a diameter gradually decreases as it approaches the substrate 30, and depths d of the recesses RE accordingly have different sizes in the Z direction.

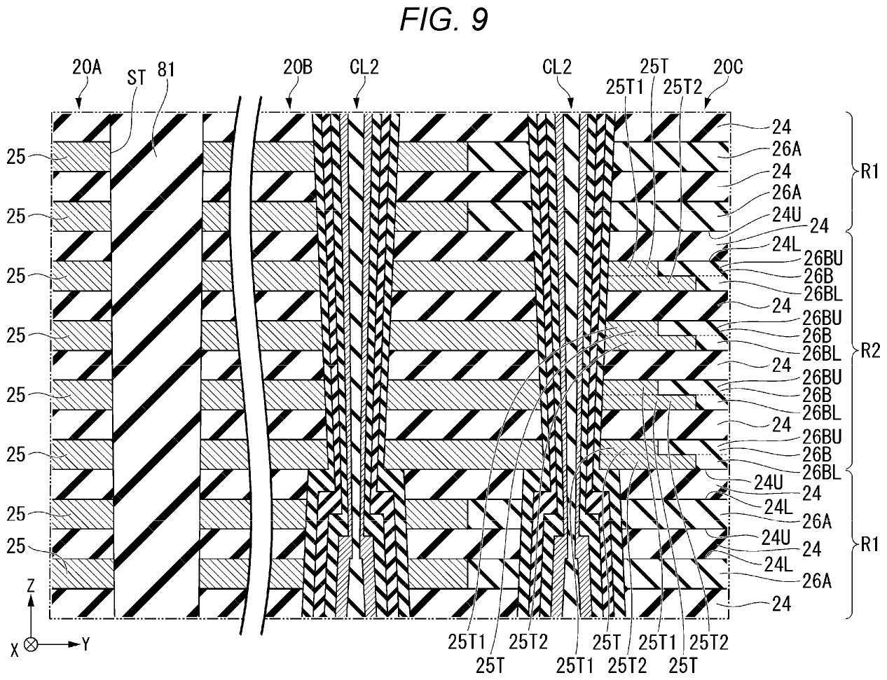

This is due to an insulating film 26B (see FIGS. 5 and 9) that is provided before the conductive film 25 is replaced. At the time of manufacture, the insulating film 26B provided in a portion where the diameter of the memory hole MH becomes smaller (reduced diameter portion Q, see FIGS. 5 and 7) is made of a material with a relatively higher etching rate than that of the insulating film 26A, and thus the insulating film 28B is etched more than the insulating film 26A at the time of forming the memory hole MH or the recess RE. In other words, the amount (depth) of the recesses RE formed on the side wall of the memory hole MH is relatively larger in the insulating film 28B. For this reason, the depths d of the recesses RE also have different sizes in the Z direction. More specifically, in a portion where the diameter of the memory hole MH becomes smaller, that is, in a region corresponding to the reduced diameter portion Q, the depth d of the recess RE becomes larger.

Each of the plurality of first columnar portions CL1 has the lower columnar portion LCL1 and the upper columnar portion UCL1. That is, the first columnar portion CL1 has a stacked structure of the lower columnar portion LCL1 and the upper columnar portion UCL1.

Each of the lower columnar portion LCL1 and the upper columnar portion UCL1 is formed in a columnar shape in which the diameter thereof on a side close to the substrate 30 is smaller and a diameter thereof gradually increases in direction away from the substrate 30 (Z direction). In the first columnar portion CL1, the reduced diameter portion Q whose diameter gradually decreases is formed in each of the lower columnar portion LCL1 and the upper columnar portion UCL1. Although FIG. 5 shows a configuration in which one reduced diameter portion Q is formed in each of the lower columnar portion LCL1 and the upper columnar portion UCL1, the number of reduced diameter portions Q is not particularly limited. For example, two or more reduced diameter portions Q may be provided in the lower columnar portion LCL1. In other words, the lower columnar portion LCL1 may have a configuration in which portions whose diameters increase and portions whose diameters decrease are alternately provided in the Z direction.

In the following description, regarding the first columnar portion CL1 which is a stacked structure of the lower columnar portion LCL1 and the upper columnar portion UCL1, when a function or a structure can be described as one first columnar portion CL1, the description will be given by referring to the lower columnar portion LCL1 and the upper columnar portion UCL1 simply as the first columnar portion CL1 without distinction therebetween.

The insulating core 60 extends in the Z direction and has a columnar shape. The insulating core 60 contains, for example, silicon oxide. The insulating core 60 is provided at a central portion including the central axis of the memory hole MH when viewed from the Z direction.

The semiconductor body 61 extends in the Z direction. The semiconductor body 61 is formed, for example, in an annular shape and covers the outer surface (outer peripheral surface) of the insulating core 60. The semiconductor body 61 contains, for example, silicon. Silicon is, for example, polysilicon obtained by crystallizing amorphous silicon. The semiconductor body 61 functions as a channel of each of the first select transistor S1, the plurality of memory cell transistors MT, and the second select transistor S2. The “channel” mentioned here is a carrier flow path between a source side and a drain side.

The semiconductor body 61 has a plurality of convex portions 61a that protrude toward the conductive film 25 side. The convex portion 61a extends from the outer surface of the semiconductor body 61 toward the conductive film 25 side between the insulating films 24 adjacent to each other in the Z direction. In other words, the convex portion 61a is provided in the corresponding recess RE. The convex portion 61a is a portion of the semiconductor body 61 and is made of the same material as the semiconductor body 61. By providing the convex portion 61a on the outer surface of the semiconductor body 61, that is, by forming a portion of the semiconductor body 61 into a shape that protrudes toward the conductive film 25 side, it is possible to concentrate an electric field in the vicinity of the convex portion 61a and to suppress interference between memory cells.

Details such as a protrusion length of the convex portion 61a will be described later.

The memory stacked film 62 extends in the Z direction. The memory stacked film 62 covers the outer surface (outer peripheral surface) of the semiconductor body 61. The memory stacked film 62 is located between the inner surface (inner peripheral surface) of the memory hole MH and the outer surface (outer peripheral surface) of the semiconductor body 61. The memory stacked film 62 includes, for example, a tunnel insulating film 63, a charge storage film 64, and a cover insulating film 65. These plurality of films are provided in the order of the tunnel insulating film 63, the charge storage film 64, and the cover insulating film 65 from the semiconductor body 61 side.

The tunnel insulating film 63 covers the outer surface of the semiconductor body 61. That is, the tunnel insulating film 63 is located between the charge storage film 64 and the semiconductor body 61. The tunnel insulating film 63 contains, for example, silicon oxide or silicon oxide and silicon nitride. The tunnel insulating film 63 is a potential barrier between the semiconductor body 61 and the charge storage film 64.

The charge storage film 64 covers the outer surface of the tunnel insulating film 63. That is, the charge storage film 64 is located between each of the conductive films 25 and the tunnel insulating film 63. The charge storage film 64 contains, for example, silicon nitride. Portions where the charge storage film 64 intersects with each of the plurality of conductive films 25 function as the memory cell transistor MT, respectively. The memory cell transistor MT stores data depending on the presence or absence of charge in the portions (charge storage portions) where the charge storage film 64 intersects with each of the plurality of conductive films 25 or the amount of stored charge. The charge storage film 64 is located between each of the conductive films 25 and the semiconductor body 61 and is surrounded by an insulating material.

In the case of the cell array area CA, the cover insulating film 65 is located, for example, between each of the insulating films 24 and the charge storage film 64. The cover insulating film 65 contains, for example, silicon oxide. The cover insulating film 65 protects the charge storage film 64 from etching during processing. The cover insulating film 65 may be omitted, or a portion thereof may be left between the conductive film 25 and the charge storage film 64 and used as a block insulating film.

In the cell array area CA, a block insulating film 71 and a barrier film 72 may be provided between each of the conductive films 25 and each of the insulating films 24 and between each of the conductive films 25 and the memory stacked film 62. The block insulating film 71 reduces back tunneling. The back tunneling is a phenomenon in which charge returns from the conductive film 25 to the memory stacked film 62. A barrier film 25b improves adhesion between the conductive film 25 and the block insulating film 71. The block insulating film 71 is, for example, a silicon oxide film or a metal oxide film. An example of a metal oxide is an aluminum oxide. For example, when the conductive film 25 is made of tungsten, the barrier film 72 is a stacked structure film of titanium nitride and titanium.

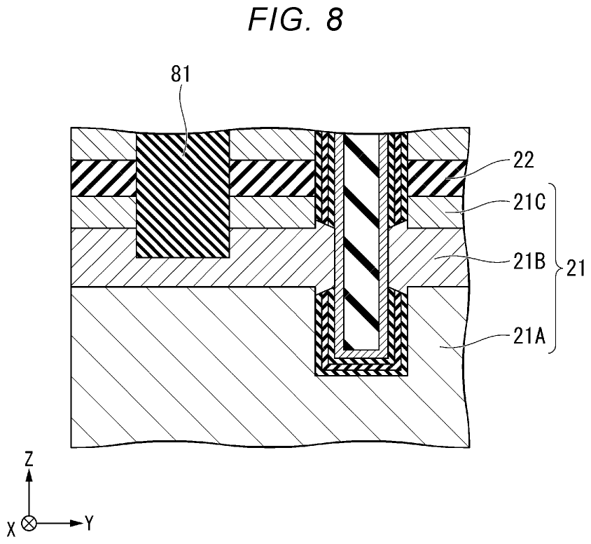

FIG. 8 is an enlarged cross-sectional view of the vicinity of the conductive film 21. FIG. 8 shows a cross-section of the conductive film 21 and the first columnar portion CL1 taken along a plane (YZ plane) parallel to the Y direction and the Z direction. As described above, the conductive film 21 includes, for example, a semiconductor layer 21A, a semiconductor layer 21B, and a semiconductor layer 21C. The conductive film 21 is connected to each of the plurality of first columnar portions CL1. The conductive film 21 is formed, for example, in a plate shape extending in the X direction and the Y direction, and functions as a source line SL. The conductive film 21 in an end area EA may also have the same structure as that in FIG. 8.

### (End Area EA)

The end area EA is an area that is located at the end of the memory cell array 10 adjacent to the cell array area CA via the slit ST in the Y direction. The end area EA includes a second stacked body 20B, a third stacked body 20C, and a plurality of second columnar portions CL2 each including the semiconductor body 61.

The second stacked body 20B, which is an area on the cell array area CA side in the end area EA, is adjacent to the slit ST in the Y direction. The second stacked body 20B may have the same structure as the first stacked body 20A described above. That is, the second stacked body 20B includes a conductive film 21, an insulating film 22, a plurality of conductive films 25, and a plurality of insulating films 24 in order from the substrate 30 side in the Z direction. The insulating film 24 is an example of a “second insulating film”, and the conductive film 25 is an example of a “second conductive film”.

On the other hand, the third stacked body 20C, which is an area on a side opposite to the cell array area CA in the end area EA, is adjacent to the second stacked body 20B on a side opposite to the slit ST, and has a structure in which the insulating films 24 and the insulating films 26 are alternately stacked in the Z direction.

The plurality of second columnar portions CL2 are provided in the second stacked body 20B and the third stacked body 20C. The plurality of second columnar portions CL2 each extend in the Z direction. For example, the plurality of second columnar portions CL2 each penetrate the second stacked body 20B and the third stacked body 20C in the Z direction. A lower portion of the second columnar portion CL2 is in contact with the semiconductor layer 21A. An upper portion of the second columnar portion CL2 is in contact with the cover insulating layer 50. A specific structure of the second columnar portion CL2 is the same as that of the first columnar portion CL1, but the second columnar portion CL2 in the end area EA is a so-called dummy pillar that does not contribute to the operation of the memory.

The cover insulating layer 50 and the bit line BL in the end area EA have the same configurations as the cover insulating layer 50 and the bit line BL in the cell array area CA.

The third stacked body 20C includes the conductive film 21, the insulating film 22, the plurality of insulating films 24 containing oxygen, the plurality of insulating films 26A containing nitrogen, and the plurality of insulating films 26B containing nitrogen in the Z direction. The plurality of insulating films 24 and the plurality of insulating films 26A are repeatedly stacked in this order in the Z direction. The plurality of insulating films 24 and the plurality of insulating films 26B are repeatedly stacked in this order in the Z direction. In the present embodiment, the insulating films 26A and 26B are an example of a “second insulating film”. The configurations of the conductive film 21 and the insulating film 22 in the end area EA are the same as the configuration of those in the cell array area CA.

Hereinafter, description will be given by referring to a structure in which the plurality of insulating films 24 and the plurality of insulating films 26A are alternately stacked in the Z direction as a “first structure R1” and referring to a structure in which the plurality of insulating films 24 and the plurality of insulating films 26B are stacked alternately in the Z direction as a “second structure R2”.

FIG. 9 is an enlarged view of a region Y shown in FIG. 5. The region Y is a region of the end area EA which includes the vicinity of a boundary between the second stacked body 20B and the third stacked body 20C. The first structures R1 and the second structures R2 are provided alternately in the Z direction.

The plurality of insulating films 24 extend in the X direction and the Y direction, respectively. The plurality of insulating films 24 contain, for example, silicon oxide. The insulating film 24 is located between the insulating films 26A or between the insulating films 26B adjacent to each other in the Z direction. At a boundary between the first structure R1 and the second structure R2, the insulating film 24 is located between the insulating film 26A and the insulating film 26B. The number of layers of the insulating films 24 is determined depending on the number of layers of the insulating films 26A and the insulating films 26B. The thickness of the insulating film 24 is, for example, 20 nm or less.

The plurality of insulating films 26A extend in the X direction and the Y direction, respectively. That is, each of the insulating films 26A is formed in a plate shape extending in the X direction and the Y direction. The insulating film 26A contains, for example, silicon nitride. The number of layers of the insulating films 26A is freely set.

The plurality of insulating films 26B extend in the X direction and the Y direction, respectively. That is, each of the insulating films 26B is formed in a plate shape that extends in the X direction and the Y direction. The insulating film 26B contains, for example, silicon nitride, and further contains oxygen or hydrogen. The number of layers of the insulating films 26B is freely set.

As shown in FIG. 9, each of the plurality of insulating films 26B includes an upper region 26BU and a lower region 26BL in the Z direction (film thickness direction). The upper region 26BU is located on a lower surface 24L side of the insulating film 24, and the lower region 26BL is located on an upper surface 24U side of the insulating film 24.

The lower region 26BL of the insulating film 26B has a higher etching rate for a first chemical than that of the upper region 26BU. The upper region 26BU and the lower region 26BL that constitute the insulating film 26B are both configured with an insulating film of such as silicon nitride. However, an etching rate for phosphoric acid is higher in the lower region 26BL than in the upper region 26BU. For this reason, as shown in FIG. 9, the cross-section of the end of the insulating film 26B on the cell array CA side has a substantially inclined shape from the upper region 26BU to the lower region 26BL. That is, the length of the lower surface of the insulating film 26B is shorter than the length of the insulating film 26A. The insulating film 26 may have a rate gradient in which an etching rate gradually increases from the lower region 26BL to the upper region 26BU.

In the present embodiment, phosphoric acid is an example of a “first chemical”.

In the insulating film 26B, the density of the lower region 26BL may be different from the density of the upper region 26BU. For example, the density of the lower region 26BL may be lower than the density of the upper region 26BU. By making the density of the lower region 26BL lower than that of the upper region 26BU, an etching rate for phosphoric acid can be increased.

In the insulating film 26B, an oxygen (O) content in the lower region 26BL may be different from an oxygen content in the upper region 26BU. For example, the oxygen content in the lower region 26BL may be lower than the oxygen content in the upper region 26BU. By making the oxygen content of the lower region 26BL lower than that of the upper region 26BU, an etching rate for phosphoric acid can be increased.

The upper region 26BU and the lower region 26BL can be distinguished using a transmission electron microscope (TEM) or the like.

In the example shown in FIG. 9, the end of the insulating film 26B in the conductive film 25 on the cell array area CA side is farther from the cell array area CA than the end of the insulating film 26A in the conductive film 25 on the cell array CA side.

Here, in the second stacked body 20B, at least one conductive film 25 among the plurality of conductive films 25 has a protrusion 25T that protrudes into the third stacked body 20C in the Y direction. For example, in the case of FIG. 9, the conductive film 25 corresponding to the insulating film 26B, that is, the conductive film 25 in the second structure R2 protrudes into the third stacked body 20C. On the other hand, the conductive film 25 corresponding to the insulating film 26A, that is, the conductive film 25 in the second structure R2, the end thereof on a side opposite to the cell array area CA does not reach the third stacked body 20C.

The conductive film 25 provided in the protrusion 25T has a first portion 25T1 and a second portion 25T2. The first portion 25T1 is located, for example, in an upper layer of the conductive film 25, and the second portion 25T2 is located in a lower layer of the conductive film. The first portion 25T1 may be located tin he lower layer of the conductive film 25, and the second portion 25T2 may be located in the upper layer of the conductive film.

The second portion 25T2 protrudes more into the third stacked body 20C than the first portion 25T1. In other words, due to a difference in an etching rate of the insulating film 26B in the thickness direction, the amount of protrusion of the end of the corresponding conductive film 25 on a side opposite to the cell array area CA varies in the film thickness direction. In the present embodiment, the individual conductive films 25, the ends of which are disposed on the side opposite to the cell array area CA and respectively have different amounts of protrusion in the film thickness direction, are an example of a “third conductive film”. It is noted that the end of the conductive film 25 on the side opposite to the cell array area CA may have a shape that is inclined from the first portion 25T1 toward the second portion T2.

The upper region 26BU and the lower region 26BL may be in contact with each other in the film thickness direction, or may be separated from each other in the film thickness direction.

Furthermore, both the upper region 26BU and the lower region 26BL may be layered and stacked on each other. That is, the insulating film 26B may have a stacked structure and have a configuration in which the upper region 26BU may be provided above the lower region 26BL.

The second structure R2 including the lower region 26BL described above is located at a position overlapping the reduced diameter portion Q in the Y direction, as shown in FIG. 5. In other words, the insulating films 26B are provided at positions overlapping the reduced diameter portions Q of the first columnar portion CL1 and the second columnar portion CL2 in the Y direction.

The insulating film 26B has a function of reducing the amount of so-called “SiN chipping” that occurs between the insulating films 24 adjacent to each other in the Z direction at the time of forming the memory hole MH by dry etching. Description regarding “SiN chipping” will be given below.

Here, a relationship between the convex portion 61a (see FIG. 7) and the first and second structures R1 and R2 in the end area EA is described. As shown in FIGS. 5 and 7, among the plurality of convex portions 61a, a length s1 of a first convex portion 61al that overlaps the protrusion 25T in the Y direction is smaller than a length s2 of a second convex portion 61a2 that does not overlap the protrusion 25T in the Y direction. That is, the length s1 of the first convex portion 61a1 that overlaps the first structure R1 in the Y direction is smaller than the length s2 of the second convex portion 61a2 that overlaps the second structure R2 in the Y direction.

The length (protrusion amount) of each of the plurality of convex portions 61a varies depending on a relative positional relationship with the reduced diameter portion Q formed in the first columnar portion CL1. That is, the lengths of the plurality of convex portions 61a differ in the Z direction. Specifically, in the first columnar portion CL1 and the second columnar portion CL2, a protrusion amount of the convex portion 61a corresponding to the reduced diameter portion Q whose diameter decreases is larger than a protrusion amount of the convex portion 61a corresponding to a portion other than the reduced diameter portion Q. This is because an etching rate of the insulating film 26B is changed in the film thickness direction. In other words, this is because, in the convex portion 61a corresponding to the position of the insulating film 26, the lower region 26BL of the insulating film 26 is actively etched at the time of forming the memory hole MH, and consequently, a large groove being a region in which the convex portion 61a is formed is easily formed in the Y direction. When the large groove is formed (in other words, the insulating film 26B is more easily etched than the insulating film 26A), the amount of SiN chipping (in other words, chipping size) can be reduced. When the amount of SiN chipping is increased, a variation in a threshold voltage increases and electrical characteristics may become unstable. However, by making the length of the convex portion 61a of the reduced diameter portion Q larger than the other regions by varying the etching rate in the film thickness direction in the insulating film 26B, it is possible to reduce the amount of SiN chipping and achieve stable electrical characteristics.

Here, as shown in FIG. 3, the semiconductor memory 1 according to the present embodiment has a plurality of slits ST and slits SHE when viewed in a plan view from the Z direction. The plurality of slits ST are grooves that divide the first stacked body 20A in the Y direction, or divide the first stacked body 20A and the second stacked body 20B in the Y direction. That is, the cell array area CA and the end area EA are separated in the Y direction due to the slits ST. All of the plurality of slits ST extend in the X direction.

The plurality of slits ST are all deep slits that penetrate the first stacked body 20A and the second stacked body 20B, and extend from the upper surface of the cover insulating layer 50 to the conductive film 21. A first separation portion 81 is disposed in the slit ST. The first separation portion 81 is an insulator containing, for example, silicon oxide. The first stacked body 20A located between the slits ST adjacent to each other in the Y direction is referred to as a block (see “BLKn” in FIG. 1), and constitutes, for example, a minimum unit for data erasure. A conductor (for example, tungsten, Poly-Si, or the like) may be disposed in the first separation portion 81.

The plurality of slits SHE are shallow slits that are provided from the upper surface of the cover insulating layer 50 to the middle of the first stacked body 20A and the middle of the second stacked body 20B. The slits SHE may be provided from the upper surface of the cover insulating layer 50 to the middle of the third stacked body 20C.

A second separation portion 82 is disposed in the slit SHE. The second separation portion 82 is an insulator containing, for example, silicon oxide. Regions separated by two adjacent slits SHE adjacent to each other in the Y direction are so-called strings (STR).

A planar layout of the memory cell array of the semiconductor memory 1 is not limited to a layout shown in FIG. 3, but may be any other layout. For example, the number and arrangement of the first columnar portions CL1 in one adjacent string may be changed as appropriate.

### <1.2 Operations>

As described above, the end area EA and the cell array area CA are separated by the slit ST. As described above, the end area EA is located at the end of the memory cell array 10 in the Y direction. The end is a region that an etching solution (for example, phosphoric acid) injected from the slit ST at the time of replacement does not reach (does not affect). In other words, in the third stacked body 20C, which is a region away from the slit ST at a certain distance in the Y direction, among the stacked bodies located in the end area EA, the insulating films 26A and 26B, which are sacrificial films, remain without being removed. However, since this end area EA is an area that does not function as a memory, there is no problem with the function of the semiconductor memory 1.

In the present embodiment, in the third stacked body 20C in the end area EA, the insulating film 26B is provided such that a plurality of regions (in the example shown in FIG. 9, two regions, that is, the upper region 26BU and the lower region 26BL) having different etching rates in the film thickness direction are formed. This is to reduce the amount (size) of SiN chipping at the time of forming the memory hole MH.

Here, “SiN chipping” will be described. The “SiN chipping” is “chipping” that occurs at an interface between the conductive film and the insulating film when carbon fluoride (CF) derived from gas (CxFy-based gas) used at the time of forming the memory hole, that is, at the time of dry etching, adheres to and is deposited on the side wall in the memory hole. Specifically, the memory hole MH is formed in a stacked body in which insulating films containing silicon oxide (for example, the insulating film 24) and insulating films containing silicon nitride (for example, the insulating film 26A) are alternately stacked. But the memory hole MH is formed by dry etching using CxFy-based gas. At this time, carbon fluoride (CF) derived from the CxFy-based gas adheres to the side wall in the memory hole MH and is deposited as a carbon fluoride film (CF film). However, since the carbon fluoride film is likely to adhere to the insulating films 26A and 26B containing silicon nitride out of the insulating film 24 and the insulating films 26A and 26B exposed on the side wall of the memory hole MH, the CF films on the side walls of the insulating films 26A and 26B become larger. In other words, a difference occurs in the film thickness of the CF film deposited on the side wall in the memory hole MH. When the diameter of the memory hole varies in the Z direction, the CF film is more likely to adhere to the side wall of the insulating film 26B corresponding to the reduced diameter portion than to an enlarged diameter portion. When the CF film on the side wall of the insulating film 26B becomes larger, the etching gas collides with the upper surface of the CF film in the Z direction, and accordingly, fluorine constituting the CF film is thermally diffused along an interface between the insulating film 24 and the insulating films 26A and 26B (particularly the insulating film 26B). As a result, SiN chipping occurs on the upper surfaces (interface) of the insulating films 26A and 26B (particularly the insulating film 26B). When components (for example, the charge storage film, the cover insulating film, and the like) of the columnar portions are formed in the memory hole MH in a state where such SiN chipping occurs, the components enter the SiN chipping, which may lead to deterioration of electrical characteristics, such as variations in a write voltage.

Consequently, in the present embodiment, the insulating film 26B having a characteristic that an etching rate varies in the film thickness direction is provided at a position corresponding to the reduced diameter portion Q where SiN chipping becomes significant, and then the memory hole MH is formed by dry etching, whereby it is possible to reduce the amount (that is, the size) of SiN chipping. In the case of the semiconductor memory 1 according to the present embodiment, the insulating film 26B is also present in the formation region of the cell array area CA in the middle of the manufacturing processing. However, since the insulating film 26B that is present in the formation region of the cell array area CA is replaced with the conductive film 25 by the replacement processing, the insulating film 26B does not remain in the cell array area CA of the semiconductor memory 1 in its final form. However, since the insulating film 26B is present in the cell array area CA in the middle of the manufacturing processing, the size of SiN chipping in the cell array area CA can be reduced. The “size of SiN chipping” mentioned herein indicates a maximum length of chipping in the Y direction at an interface between the insulating film 26A and the insulating film 24 and an interface between the insulating film 26B and the insulating film 24.

As described above, in most of the memory cell array 10 (excluding the end area EA), the insulating film 26A and the insulating film 26B are replaced with the conductive film 25 by replacement. For this reason, at least in the cell array area CA, the insulating film 26A and the insulating film 26B are removed and do not remain. However, some regions of the end area EA (particularly the third stacked body 20C, which is the end on a side opposite to the cell array area CA) are hardly affected by the replacement, and thus whether the replacement is performed using the insulating film 26B can be determined in accordance with the configuration of the third stacked body 20C in the end area EA, that is, whether the insulating film 26B remains in the third stacked body 20C.

As described above, in the semiconductor memory 1 of the present embodiment, the insulating film 26B having a plurality of regions having different etching rates in the film thickness direction is provided at a position corresponding to the reduced diameter portion Q of the first columnar portion CL1, and thus it is possible to increase the amount of recess in the insulating film 26B in the reduced diameter portion Q and consequently reduce the size of SiN chipping that occurs at the time of forming the memory hole MH. As a result, electrical characteristics of the semiconductor memory 1 can be improved.

### <2. Method of Manufacturing Semiconductor Memory>

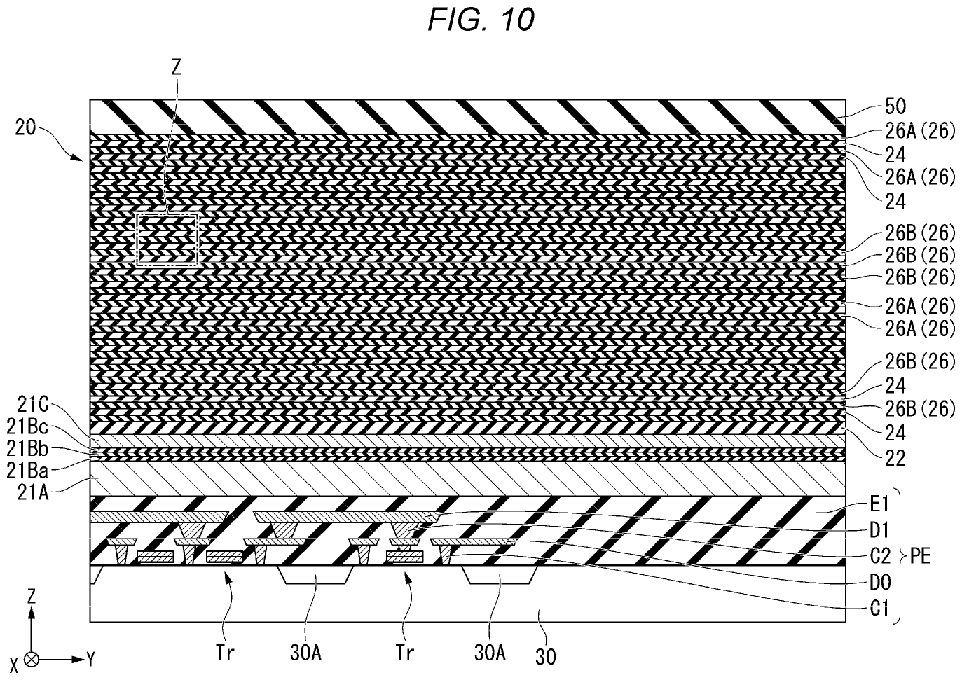

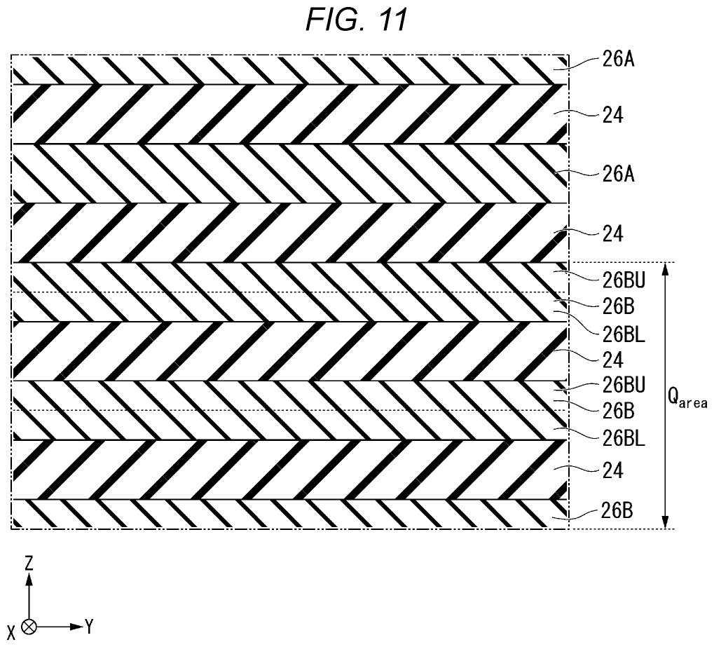

Next, a method of manufacturing the semiconductor memory 1 according to the present embodiment will be described. FIGS. 10 to 16 are cross-sectional views illustrating a method of manufacturing the semiconductor memory 1 according to the present embodiment. FIG. 11 is an enlarged view of a region Z in FIG. 10.

First, as shown in FIG. 10, an element separation region 30A is formed in the substrate 30, and the transistor Tr is formed in the circuit layer PE. The transistor Tr can be manufactured by a known method. In the circuit layer PE, a plurality of wiring layers D0 and D1 and a plurality of vias C1 and C2 that are electrically connected to the transistor Tr are formed in the insulating layer E1. The plurality of wiring layers D0 and D1 and the plurality of vias C1 and C2 can be manufactured by a known method.

Next, the semiconductor layer 21A, an intermediate film 21Ba, a first sacrificial film 21Bb, an intermediate film 21Bc, the semiconductor layer 21C, and the insulating film 22 are stacked in this order on the circuit layer PE. The intermediate film 21Ba and the intermediate film 21Bc contain, for example, silicon oxide. The first sacrificial film 21Bb is made of, for example, silicon nitride. The semiconductor layer 21A, the semiconductor layer 21C, and the insulating film 22 are the same as those described above.

Next, the insulating films 24 and the insulating films 26 (26A, 26B) are alternately stacked on the insulating film 22 to form the stacked body 20 (stack step). The insulating film 26B is formed at a position corresponding to an area Qₐᵣₑₐ (see FIG. 5) corresponding to the reduced diameter portion Q of the first columnar portion CL1.

Specifically, as shown in FIG. 11, the insulating films 24 and the insulating films 26B are alternately stacked in the area Qₐᵣₑₐ corresponding to the reduced diameter portion Q, and the insulating films 24 and the insulating films 26A are alternately stacked in an area other than the area Qₐᵣₑₐ corresponding to the reduced diameter portion Q. The insulating film 24 is formed as described above and contains, for example, silicon oxide. Both the insulating film 26A and the insulating film 26B contain, for example, silicon nitride, but the insulating film 26B includes the upper region 26BU and the lower region 26BL, and the lower region 26BL has a higher etching rate for the first chemical (for example, phosphoric acid) than that of the upper region 26BU.

Here, a method of forming the insulating film 26B will be described. The insulating film 26B is a film containing silicon nitride as a main component. Oxygen may be added to the silicon nitride. The upper region 26BU and the lower region 26BL of the insulating film 26B differ only in an etching rate, and have in common that they both contain SiN as a main component. Thus, although the upper region 26BU and the lower region 26BL may be formed individually, they can also be formed successively by plasma chemical vapor deposition (CDV). For example, the upper region 26BU can be formed by appropriately changing film formation conditions (for example, a flow rate of gas, a pressure, power of a power supply) in the middle of film formation of the lower region 26BL. A density gradient in the film thickness direction of the insulating film 26B can also be adjusted by appropriately controlling the film formation conditions described above.

Next, as shown in FIG. 10, the cover insulating layer 50 is formed on the insulating film 26A located at the uppermost portion to form the stacked body 20.

Next, the memory holes MH are formed in the stacked body 20 (etching step). The memory holes MH extend from the upper surface of the stacked body 20 to the middle of the semiconductor layer 21A. The memory holes MH are manufactured by etching. For example, anisotropic etching is performed from the upper surface of the stacked body 20 to the semiconductor layer 21A.

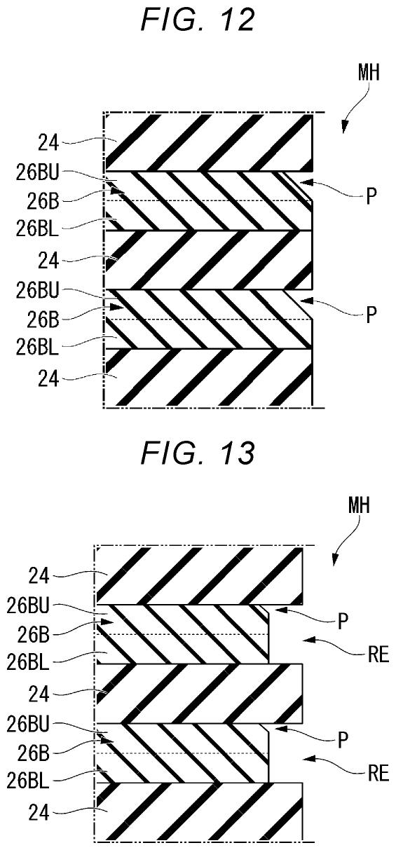

FIG. 12 is an enlarged cross-sectional view of the insulating films 24 and the insulating films 26B at the time of forming the memory hole MH. As described above, when the memory hole is formed (when anisotropic etching is performed), SiN chipping P occurs at an interface between insulating films. Since the SiN chipping affects electrical characteristics of the semiconductor memory 1, SiN chipping with a smaller size is preferable. On the other hand, since the insulating film 26 according to the present embodiment is provided with the lower region 26BL with a relatively high etching rate, a portion of the lower region 26BU may also be etched when the memory hole MH is formed (see FIG. 12). In other words, the lower region 26BU is etched in preference to the upper region 26BU, and thus the apparent size of the SiN chipping can be reduced.

The anisotropic etching is performed using, for example, a gas G containing a carbon element and a fluorine element. The gas G contains, for example, a CₓH_{y}F_{z} gas. However, C represents carbon, H represents hydrogen, F represents fluorine, x represents an integer of 1 or more, y represents an integer of 0 or more, and z represents an integer of 1 or more (x≥1, y≥0, z≥1). When y=0, CₓH_{y}F_{z} is a fluorocarbon, and when y≠0, CₓH_{y}F_{z} is a hydrofluorocarbon. Examples of the CₓH_{y}F_{z} gas include a C₄F₆ gas, a C₄F₈ gas, and a CH₂F₂ gas.

Next, a groove (recess RE) that is recessed toward the insulating film 26B side is formed in a portion of the side wall of the memory hole MH (recess step).

FIG. 13 is an enlarged cross-sectional view of the insulating films 24 and the insulating films 26B at the time of forming the recess RE. Also in the recess step, the lower region 26BU is etched in preference to the upper region 26BU, as in the case of forming the memory hole MH. Thereby, the apparent size of SiN chipping can be reduced.

The size of SiN chipping is larger in an area where the diameter of the memory hole MH is smaller. For this reason, the insulating film 26B is disposed at a portion where the diameter of the memory hole MH becomes smaller (corresponding to the reduced diameter portion Q), and thus the effect of reducing the size of SiN chipping can be more effectively exhibited.

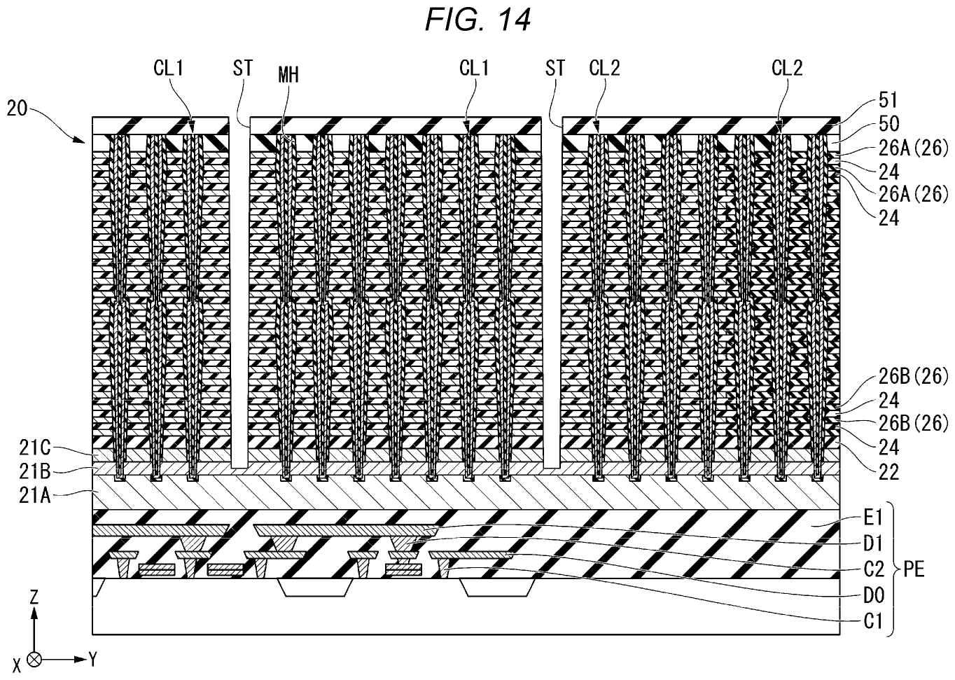

Next, as shown in FIG. 14, the memory stacked film 62, the semiconductor body 61, and the insulating core 60 are sequentially formed in the memory hole MH. The memory hole MH is filled with the memory stacked film 62, the semiconductor body 61, and the insulating core 60. Thereby, the first columnar portion CL1 and the second columnar portion CL2 are formed in the memory hole MH. Annealing processing may be appropriately performed on the first columnar portion CL1 and the second columnar portion CL2.

Next, the cover insulating layer 51 is formed on the stacked body 20 in which the first columnar portion CL1 and the second columnar portion CL2 are formed. Thereafter, a plurality of slits ST are formed in the stacked body 20. The slit ST is a deep slit and extends from the upper surface of the stacked body 20 to the middle of the sacrificial film 21Bb. The slit ST is formed by anisotropic etching. A stopper film is formed on the inner wall of the slit ST. The stopper film is made of, for example, silicon oxide.

Next, isotropic etching is performed on the sacrificial film 21Bb through the slits ST. The sacrificial film 21Bb is removed by isotropic etching. The isotropic etching is performed using an etchant by which silicon nitride can be etched more rapidly than silicon oxide. A portion of the memory stacked film 62 is also removed by further etching. A portion of the memory stacked film 62 which is exposed by removing the sacrificial film 21Bb is removed. By removing a portion of the memory stacked film 62, a portion of the semiconductor body 61 is exposed. Etching of the memory stacked film 62 is performed using an etchant by which silicon oxide can be etched more rapidly than silicon nitride. In the etching of the memory stacked film 62, the intermediate films 21Ba and 21Bc and the stopper film are also removed at the same time as the memory stacked film 62. A space is formed between the semiconductor layer 21A and the semiconductor layer 21C.

Next, as shown in FIG. 14, the space is filled with a semiconductor material through the slits ST to form the semiconductor layer 21B. Thereby, the exposed semiconductor body 61 and the semiconductor layer 21B come into contact with each other. The material of the semiconductor layer 21B is as described above. The semiconductor layer 21B contains, for example, phosphorus.

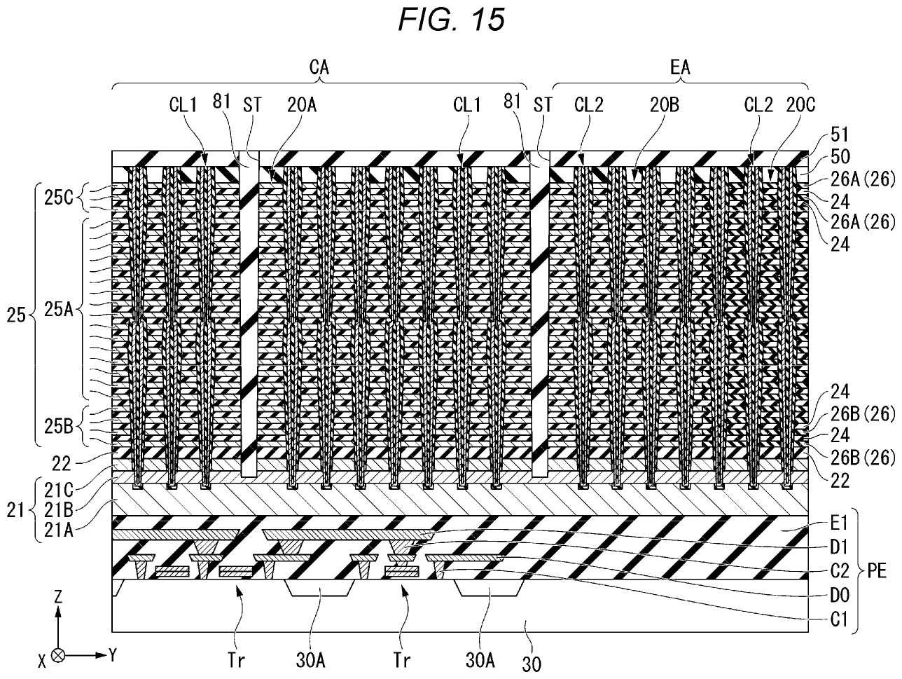

Next, as shown in FIG. 15, the insulating films 26A and the insulating films 26B are replaced with the conductive films 25. First, the insulating films 26A and the insulating films 26B are removed through the slits ST. The insulating films 26A and the insulating films 26B are removed by isotropic etching. The isotropic etching is performed using an etchant by which silicon nitride can be etched more rapidly than silicon oxide and polysilicon. However, at this time, the etchant does not reach (does not affect) a portion of the end area EA, and thus the insulating films 26A and the insulating films 26B, which are sacrificial films, remain without being removed. In other words, portions of the insulating film 26A and the insulating film 26B are not replaced with the conductive films 25.

Thereafter, the portions where the insulating films 26A and the insulating films 26B are removed are filled with a conductive material to form the conductive films 25. Thereby, the first stacked body 20A, the second stacked body 20B, and the third stacked body 20C are formed.

Next, the first separation portion 81 is formed by filling the inside of the slit ST with an insulator. Thereby, the cell array area CA and the end area EA are separated in the Y direction.

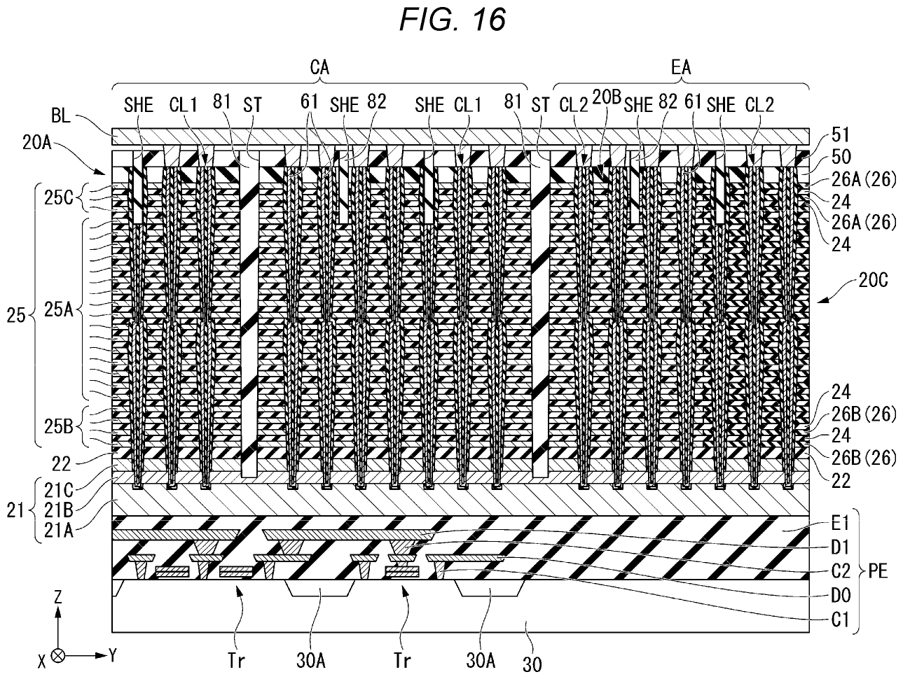

Next, as shown in FIG. 16, the plurality of slits SHE are formed. Each of the plurality of slits SHE extends from at least the upper surfaces of the first stacked body 20A, the second stacked body 20B, and the third stacked body 20C to a depth corresponding to the conductive film 25C (drain-side select gate line SGD). The plurality of SHE are manufactured by etching. For example, anisotropic etching is performed from the upper surfaces of the first stacked body 20A, the second stacked body 20B, and the third stacked body 20C to a depth corresponding to the conductive film 25C (drain-side select gate line SGD). The anisotropic etching is, for example, reactive ion etching (RIE). Next, the second separation portion 82 is formed by filling the plurality of slits SHE with an insulator.

Next, the bit lines BL are provided above the first stacked body 20A, the second stacked body 20B, and the third stacked body 20C.

Through the above steps, the semiconductor memory 1 according to at least one embodiment is manufactured. The manufacturing steps shown here are merely examples, and other steps may be inserted between the steps.

Although some embodiments are described above, the embodiments are not limited to the above-described examples. For example, a memory film may be a ferroelectric film provided in a ferroelectric FET (FeFET) memory that stores data based on the direction of polarization. The ferroelectric film is made of, for example, hafnium oxide.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory comprising:
a first stacked body including a plurality of first insulating films and a plurality of first conductive films alternately stacked in a first direction;
a first separation portion adjacent to the first stacked body in a second direction intersecting the first direction, the first separation portion including an insulator extending in the first direction and a third direction, the third direction intersecting the first direction and the second direction;
a second stacked body adjacent to the first separation portion in the second direction and including a plurality of second insulating films and a plurality of second conductive films alternately stacked in the first direction;
a third stacked body adjacent to the second stacked body in the second direction, the plurality of second insulating films and a plurality of third insulating films alternately stacked in the first direction; and
a bit line disposed on an upper side of the first stacked body in the first direction,
wherein the first stacked body includes a first semiconductor layer and has a first columnar portion extending in the first direction, and
at least one layer of a selected second conductive film among the plurality of second conductive films has:
a first portion; and
a second portion located below the first portion in the first direction and formed to protrude further into the third stacked body than the first portion in the second direction.

2. The semiconductor memory according to claim 1,
wherein at least one layer of the selected third insulating film among the plurality of third insulating films has an upper region and a lower region, the lower region located below the upper region in the first direction, and
the lower region having a higher etching rate for a first chemical than an etching rate for the first chemical in the upper region.

3. The semiconductor memory according to claim 1,
wherein the first columnar portion is disposed in a memory hole extending in the first direction,
a plurality of recesses formed on a side wall of the memory hole, the recesses being recessed toward the plurality of first conductive films, and
depths of the plurality of recesses are different in the first direction.

4. The semiconductor memory according to claim 1,
wherein at least two layers of two selected second conductive films among the plurality of second conductive films each have the first portion and the second portion, and
each of the second portions respectively has a different protrusion in the second direction.

5. The semiconductor memory according to claim 2,
wherein the first chemical is phosphoric acid.

6. The semiconductor memory according to claim 2,
wherein the lower region has a density different from a density of the upper region.

7. The semiconductor memory according to claim 2,
wherein, in the at least one layer of the selected third insulating film among the plurality of third insulating films, an oxygen content in the lower region is lower than an oxygen content in the upper region.

8. The semiconductor memory according to claim 1,
wherein the first columnar portion has an upper columnar portion and a lower columnar portion, the lower columnar portion located below the upper columnar portion,
both the upper columnar portion and the lower columnar portion have a reduced diameter portion whose diameter decreases downward in the first direction, and
the reduced diameter portion and the third conductive film are located at positions overlapping each other in the second direction.

9. The semiconductor memory according to claim 5,
wherein the first columnar portion has an upper columnar portion and a lower columnar portion, the lower columnar portion located below the upper columnar portion,
both the upper columnar portion and the lower columnar portion have a reduced diameter portion whose diameter decreases downward in the first direction, and
the reduced diameter portion and the third conductive film are located at positions overlapping each other in the second direction.

10. The semiconductor memory according to claim 1, further comprising a second columnar portion including a second semiconductor layer and extending in the first direction in the second stacked body.

11. A method of manufacturing a semiconductor memory, the method comprising:
forming a first stacked body of a first insulating film and a second insulating film stacked in a first direction;
forming a memory hole in the first direction in the first stacked body including performing dry etching on the first stacked body using a gas containing carbon and fluorine;
forming, using a first chemical, a groove recessed in a second direction intersecting the first direction on the first insulating film in a portion of a side wall of the memory hole; and
forming a bit line above the first stacked body,
wherein the first stacked body is formed by alternately depositing the first insulating film and the second insulating film a plurality of times, and
the second insulating film is formed by performing, after deposition of a lower region, deposition of an upper region having a lower etching rate for the first chemical than an etching rate for the first chemical in the lower region.

12. The method of manufacturing the semiconductor memory according to claim 11,
wherein the lower region has a density different from a density of the upper region.

13. The method of manufacturing the semiconductor memory according to claim 11,
wherein an oxygen content in the lower region is lower than an oxygen content in the upper region.

14. The method of manufacturing the semiconductor memory according to claim 11, further comprising:
forming, in the memory hole, a first columnar portion having an upper columnar portion and a lower columnar portion, the lower columnar portion located below the upper columnar portion and including a first semiconductor layer, after the forming of the groove,
wherein both the upper columnar portion and the lower columnar portion have a reduced diameter portion whose diameter decreases downward in the first direction.

15. The method of manufacturing the semiconductor memory according to claim 11,
wherein the second insulating film has a film thickness of 1 nm or more.

16. The method of manufacturing the semiconductor memory according to claim 11, wherein the first insulating film is composed of silicon oxide.

17. The method of manufacturing the semiconductor memory according to claim 11, wherein the first insulating film has a thickness of 20 nm or less.
